(19) United States
(12) Patent Application Publication
(10) Pub. No.: US 2004/0027177 A1
(43) Pub. Date: Feb. 12, 2004

(54) Semiconductor integrated circuit

(75) Inventor: Kazuo Aoki, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/356,626

(22) Filed: Feb. 3, 2003

(30) Foreign Application Priority Data
Aug. 7, 2002 (JP) 2002-230412

(51) Int. Cl. H03B 1/00

(52) U.S. Cl. 327/108

(57) ABSTRACT

A detection circuit detects an output impedance of a monitoring output buffer inclusive of an impedance of a pattern wiring having a wiring length equal to an average value of wiring lengths of pattern wirings on a package substrate, and a control signal generating circuit controls the output impedances of output buffers and the monitoring output buffer to match with a predetermined impedance on the basis of the output impedance detected by the detection circuit.

### BACKGROUND OF THE INVENTION

1. Field of the Invention

The present invention relates to a semiconductor integrated circuit in which a semiconductor chip mounted on a package substrate is sealed by a package.

2. Description of Related Art

FIG. 3 is a block diagram showing a configuration of an output circuit of a conventional semiconductor integrated circuit.

Referring to FIG. 3, reference numerals 1a and 1b denote output buffers whose output impedance can be changed, 2 denotes a monitoring output buffer having the same circuit configuration as the output buffers 1a and 1b, whose output impedance can be changed, 3 donates a detection circuit for detecting the output impedance of the monitoring output buffer 2, 4 denotes a control signal generating circuit for generating a control signal so as to match with a predetermined output impedance on the basis of the output impedance of the monitoring output buffer 2 which is detected by the detection circuit 3, and 5 denotes an output impedance control circuit made up of the monitoring output buffer 2, the detection circuit 3 and the control signal generating circuit 4.

Further, reference numerals 6a and 6b denote connection terminals (pads) connected to the output buffers 1a and 1b, respectively, 7a and 7b denote wires connected to the connection terminals 6a and 6b, respectively, 8a and 8b denote pattern wirings connected to the wires 7a and 7b, respectively, 9a and 9b denote external terminals connected to the pattern wirings 8a and 8b, respectively, and formed of solder balls, 11 denotes a semiconductor chip on which the output buffers 1a and 1b, the output impedance control circuit 5 and the connection terminals 6a and 6b are mounted, and 12 denotes a package substrate on which the pattern wirings 8a and 8b and the external terminals 9a and 9b, as well as the semiconductor chip 11 are mounted. As shown in FIG. 3, the connection terminals 6a and 6b formed on the semiconductor chip 11 and the pattern wirings 8a and 8b formed on the package substrate 12 are connected by the wires 7a and 7b, respectively.

FIG. 4 is an external view showing an exemplary plastic mold BGA (Ball Grid Array) package in which a chip is sealed.

Referring to FIG. 4 reference numeral 13 denotes a plastic mold, and other constituents, i.e., a connection terminal 6, a wire 7, a pattern wiring 8, an external terminal 9 and the semiconductor chip 11 and the package substrate 12 are the same as those of FIG. 3. As shown in FIG. 4, the connection terminals 6 which are formed of solder balls two-dimensionally arranged on the semiconductor chip 11 and the external terminals 9 of a package in which the semiconductor chip 11 is sealed are connected by pattern wirings on the package substrate 12.

The operation of the conventional semiconductor integrated circuit will now be described.

In FIG. 3, the detection circuit 3 detects the output impedance of the monitoring output buffer 2. When the output impedance detected by the detection circuit 3 does not match with the predetermined impedance, the control signal generating circuit 4 outputs the control signal for controlling the detected output impedance to the output buffers 1a and 1b and the monitoring output buffer 2 so as to match with the predetermined output impedance.

The monitoring output buffer 2 changes its output impedance in accordance with the control signal outputted from the control signal generating circuit 4. The detection circuit 3 detects the changed output impedance of the monitoring output buffer 2, and when the output impedance detected by the detection circuit 3 still does not match with the predetermined impedance, the control signal generating circuit 4 outputs the control signal for controlling the detected output impedance so as to match with the predetermined impedance. The above operation is repeated until the output impedance of the monitoring output buffer 2 matches with the predetermined impedance.

Since the control signal from the control signal generating circuit 4 is also outputted to the output buffers 1a and 1b on the same semiconductor chip 11, the output impedances of the output buffers 1a and 1b are also controlled to match with the predetermined impedance. Such a control of the output impedances acts as an auto-control function against manufacturing dispersion of the semiconductor chip 11 and changes in supply voltage and temperature, and the output impedances of the output buffers 1a and 1b are always controlled to match with the predetermined impedance.

However, the output buffers 1a and 1b formed on the semiconductor chip 11 are connected to the external terminals 9a and 9b of the package, which are formed of solder balls, by the pattern wirings 8a and 8b on the package substrate 12, respectively. Thus, the output impedances of the output buffers 1a and 1b actually include the impedances of the pattern wirings 8a and 8b on the package substrate 12, respectively, and the like.

Since the conventional semiconductor integrated circuit is thus configured as above and the output impedance control circuit 5 measures only the output impedance of the monitoring output buffer 2 provided inside the semiconductor chip 11, in other words, measures only the output impedances of the output buffers 1a and 1b, and controls the output impedances so as to match with the predetermined one, the measured output impedances fails to include the impedances of the pattern wirings 8a and 8b and the like extending from the connection terminals 6a and 6b on the semiconductor chip 11 to the external terminals 9a and 9b on the package substrate, which are included in the actual output impedances of the output buffers 1a and 1b. Therefore, when the output impedances of the output buffers 1a and 1b are changed due to the manufacturing dispersion of the semiconductor chip 11 and changes in supply voltage and temperature, the auto-control function starts to match the output impedances of the output buffers 1a and 1b with the predetermined impedance. However, when a wiring impedance of the package substrate 12 is changed due to manufacturing dispersion of package constituent members, the output impedances cannot be matched with the predetermined impedance.

As a prior art providing a solution to the above problem, the invention entitled “SEMICONDUCTOR INTEGRATED CIRCUIT AND METHOD OF CONTROLLING IMPEDANCE” is disclosed in Publication of Japanese Patent Application No. 2001-127614, which reads that the output impedance of each output buffer is controlled by connecting a feedback pattern wiring whose length is equal to that of the pattern wirings connected to the output buffers to a controlling output buffer. But the lengths of the pattern wirings connected to the output buffers are often not uniform, which makes it impossible to control the output impedances of the output buffers with the same accuracy.

### SUMMARY OF THE INVENTION

The present invention has been made to solve the above problem and an object thereof is to provide a semiconductor integrated circuit which is able to control impedances of buffers so as to match with a predetermined impedance against manufacturing dispersion of a semiconductor chip, changes in supply voltage and temperature and manufacturing dispersion of package constituent members, as well as control the impedances of the buffers with the same accuracy even if the lengths of pattern wirings connected to the buffers are not uniform.

The semiconductor integrated circuit according to the present invention includes a plurality of first buffers connected to a plurality of first connection terminals on a semiconductor chip, and whose impedances at the first connection terminals can be controlled by a control signal, a second buffer having the same circuit configuration as the first buffers, being connected to a second connection terminal on the semiconductor chip, and whose impedance at the second connection terminal can be controlled by the control signal, a second pattern wiring formed on a package substrate, being connected to the second connection terminal, having a wiring length equal to an average value of wiring lengths of a plurality of first pattern wirings, a detection circuit for detecting the impedance at the second connection terminal inclusive of an impedance of the second pattern wiring, and a control signal generating circuit for generating the control signal which controls the impedances of the first and second buffers so as to match with a predetermined impedance on the basis of the impedance detected by the detecting circuit.

Therefore, according to the semiconductor integrated circuit of the present invention, it is possible to always control the impedances of the first buffers so as to match with a predetermined impedance against manufacturing dispersion of the semiconductor chip, changes in supply voltage and temperature and manufacturing dispersion of package constituent members, as well as control the impedances of the first buffers with the same accuracy even if the lengths of pattern wirings connected to the first buffers are not uniform.

### BRIEF DESCRIPTION OF THE DRAWINGS

FIG. 1 is a block diagram showing a configuration of an output circuit of a semiconductor integrated circuit according to a first embodiment;

FIG. 2 is a block diagram showing a configuration of an input circuit of a semiconductor integrated circuit according to a second embodiment;

FIG. 3 is a block diagram showing a configuration of an output circuit of a conventional semiconductor integrated circuit; and

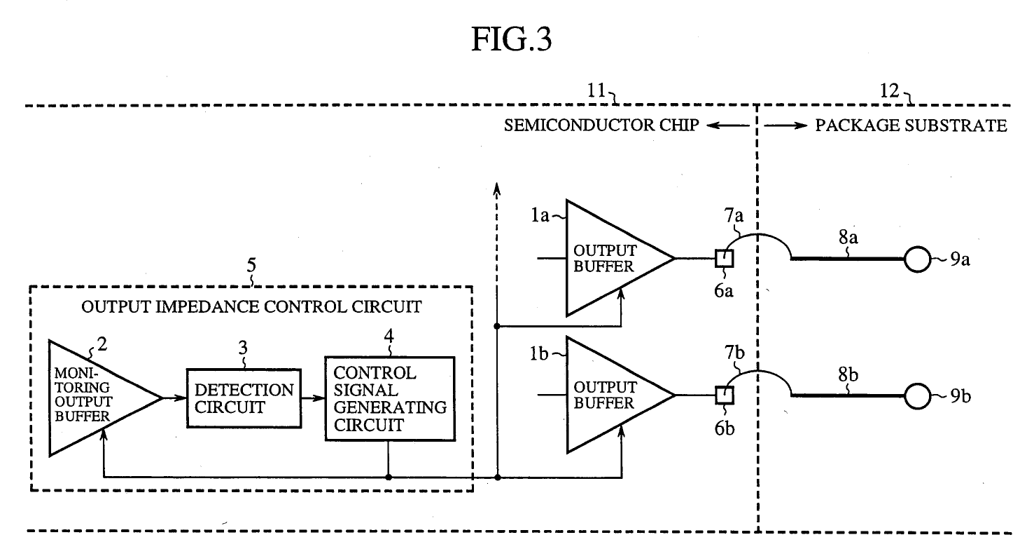

FIG. 4 is an external view showing an exemplary plastic mold BGA package in which a chip is sealed.

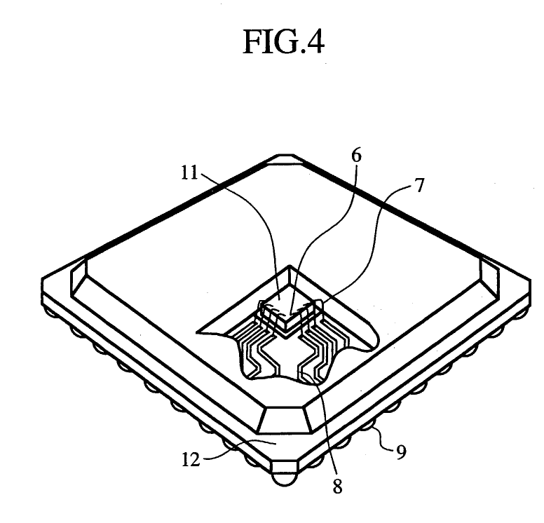

### DETAILED DESCRIPTION OF THE PREFERRED EMBODIMENTS

The preferred embodiments of the present invention will next be described hereinafter with reference to the attached drawings.

### First Embodiment

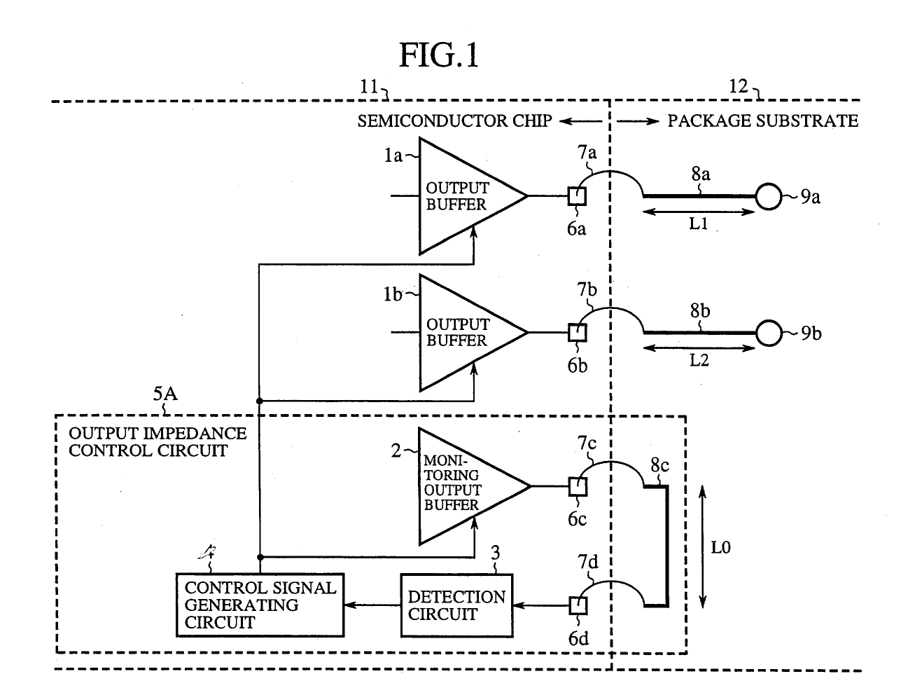

FIG. 1 is a block diagram showing a configuration of an output circuit of a semiconductor integrated circuit according to the first embodiment. The semiconductor integrated circuit of the first embodiment is also sealed in a BGA package like the conventional one.

Referring to FIG. 1, reference numerals 1a and 1b denote output buffers (first buffers) whose output impedance can be changed, 6a and 6b denote connection terminals (pads, first connection terminals) connected to the output buffers 1a and 1b, respectively, 7a and 7b denote wires connected to the connection terminals 6a and 6b, respectively, 8a and 8b denote pattern wirings (first pattern wirings) connected to the wires 7a and 7b, respectively, and 9a and 9b denote external terminals connected to the pattern wirings 8a and 8b, respectively, and formed of solder balls.

Further, reference numeral 2 denotes a monitoring output buffer (second buffer) having the same circuit configuration as the output buffers 1a and 1b, whose output impedance can be changed, 6c denotes a connection terminal (pad, second connection terminal) connected to the monitoring output buffer 2, 7c denotes a wire connected to the connection'terminal 6c, 8c denotes a pattern wiring (second pattern wiring) connected to the wire 7c, 7d is a wire connected to the pattern wiring 8c, and 6d denotes a connection terminal (pad) connected to the wire 7d.

Further, reference numeral 3 donates a detection circuit for detecting the output impedance of the monitoring output buffer 2 inclusive of impedances of the wires 7c and 7d and the pattern wiring 8c, 4 denotes a control signal generating circuit for generating a control signal so as to match with a predetermined output impedance on the basis of the output impedance of the monitoring output buffer 2 inclusive of the impedances of the wires 7c and 7d and the pattern wiring 8c which is detected by the detection circuit 3, and 5A denotes an output impedance control circuit made up of the monitoring output buffer 2, the connection terminals 6c and 6d, the wires 7c and 7d, the pattern wiring 8c, the detection circuit 3 and the control signal generating circuit 4.

Further, reference numeral 11 denotes a semiconductor chip on which the output buffers 1a and 1b, the monitoring output buffer 2, the detection circuit 3, the control signal generating circuit 4 and the connection terminals 6a, 6b, 6c and 6d are mounted, and 12 denotes a package substrate on which the pattern wirings 8a, 8b and 8c and the external terminals 9a and 9b, as well as the semiconductor chip 11 are mounted. As shown in FIG. 1, the connection terminals 6a and 6b on the semiconductor chip 11 and the pattern wirings 8a and 8b on the package substrate 12 are connected by the wires 7a and 7b, respectively, and the connection terminals 6c and 6d on the semiconductor chip 11 and the pattern wiring 8c on the package substrate 12 are connected by the wires 7c and 7d, respectively.

In FIG. 1, assuming that the wiring length of the pattern wiring 8a connected to the output buffer 1a is L1, the wiring length of the pattern wiring 8b connected to the output buffer 1b is L2 and the wiring length of the pattern wiring 8c of the output impedance control circuit 5A is L0, the wiring length L0 is set to an average value of the wiring lengths L1 and L2. That is, L0=(L1+L2)/2.

The operation of the semiconductor integrated circuit of the first embodiment will now be described.

The detection circuit 3 detects the output impedance of the monitoring output buffer 2 inclusive of the impedances of the wires 7c and 7d and the pattern wiring 8c. When the output impedance detected by the detection circuit 3 does not match with the predetermined impedance, the control signal generating circuit 4 outputs the control signal for controlling the detected output impedance to the output buffers 1a and 1b and the monitoring output buffer 2 so as to match with the predetermined output impedance.

The monitoring output buffer 2 changes its output impedance in accordance with the control signal outputted from the control signal generating circuit 4. The detection circuit 3 detects the changed output impedance of the monitoring output buffer 2 inclusive of the impedances of the wires 7c and 7d and the pattern wiring 8c, and when the output impedance detected by the detection circuit 3 still does not match with the predetermined impedance, the control signal generating circuit 4 outputs the control signal for controlling the detected output impedance so as to match with the predetermined output impedance. The above operation is repeated until the output impedance of the monitoring output buffer 2 inclusive of the impedances of the wires 7c and 7d and the pattern wiring 8c matches with the predetermined output impedance.

Since the control signal from the control signal generating circuit 4 is also outputted to the output buffers 1a and 1b on the same semiconductor chip 11, the output impedances of the output buffers 1a and 1b are also controlled so as to match with the predetermined output impedance. Such a control of the output impedances acts as an auto-control function for the change in impedance due to manufacturing dispersion of the semiconductor chip 11 and changes in supply voltage and temperature, and also due to manufacturing dispersion of package constituent members, and the output impedances of the output buffers 1a and 1b are always controlled so as to match with the predetermined output impedance.

By setting the wiring length L0 of the pattern wiring 8c of the output impedance control circuit 5A to the average value of the wiring lengths L1 and L2 of the pattern wirings 8a and 8b connected to the output buffers 1a and 1b, respectively, it is possible to control the output impedances of all the output buffers 1a and 1b with the same accuracy.

As discussed above, according to the first embodiment, since the detection circuit 3 detects the output impedance of the monitoring output buffer 2 inclusive of the impedances of the wires 7c and 7d and the pattern wiring 8c having the wiring length which is an average value of the wiring lengths of the pattern wirings 8a and 8b connected to the output buffers 1a and 1b, respectively, and when the detected output impedance does not match with the predetermined impedance, the control signal generating circuit 4 outputs the control signal for controlling the detected output impedance to the output buffers 1a and 1b and the monitoring output buffer 2 so as to match with the predetermined output impedance, it is possible to actuate the auto-control function for the change in impedance due to manufacturing dispersion of the semiconductor chip 11, changes in supply voltage and temperature and manufacturing dispersion of package constituent members, to always control the output impedances of the output buffers 1a and 1b so as to match with the predetermined output impedance and the output impedances of the output buffers 1a and 1b can be controlled with the same accuracy even if the lengths of the pattern wirings 8a and 8b connected to the output buffers 1a and 1b are not uniform.

### Second Embodiment

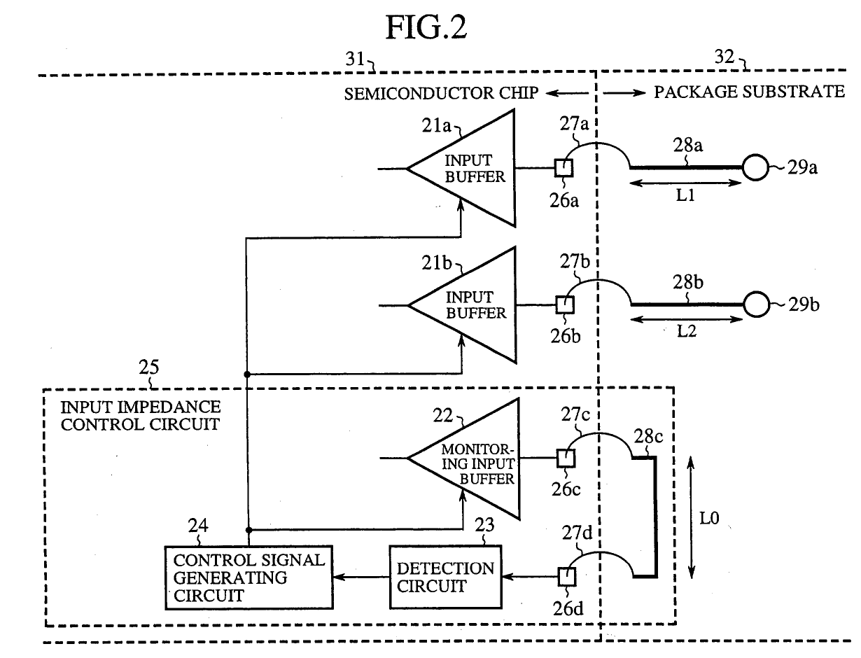

FIG. 2 is a block diagram showing a configuration of an input circuit of a semiconductor integrated circuit according to the second embodiment. The semiconductor integrated circuit of the second embodiment is also sealed in a BGA package in the same manner as with the first embodiment.

Referring to FIG. 2, reference numerals 21a and 21b denote input buffers (first buffers) whose input impedance can be changed, 26a and 26b denote connection terminals (pads, first connection terminals) connected to the input buffers 21a and 21b, respectively, 27a and 27b denote wires connected to the connection terminals 26a and 26b, respectively, 28a and 28b denote pattern wirings (first pattern wirings) connected to the wires 27a and 27b, respectively, and 29a and 29b denote external terminals connected to the pattern wirings 28a and 28b, respectively, and formed of solder balls.

Further, reference numeral 22 denotes a monitoring input buffer (second buffer) having the same circuit configuration as the input buffers 21a and 21b, whose input impedance can be changed, 26c denotes a connection terminal (pad, second connection terminal) connected to the monitoring input buffer 22, 27c denotes a wire connected to the connection terminal 26c, 28c denotes a pattern wiring (second pattern wiring) connected to the wire 27c, 27d is a wire connected to the pattern wiring 28c, and 26d denotes a connection terminal (pad) connected to the wire 27d.

Further, reference numeral 23 donates a detection circuit for detecting the input impedance of the monitoring input buffer 22 inclusive of impedances of the wires 27c and 27d and the pattern wiring 28c, 24 denotes a control signal generating circuit for generating a control signal so as to match with a predetermined impedance on the basis of the input impedance of the monitoring input buffer 22 inclusive of the impedances of the wires 27c and 27d and the pattern wiring 28c which is detected by the detection circuit 23, and 25 denotes an input impedance control circuit constituting of the monitoring input buffer 22, the connection terminals 26c and 26d, the wires 27c and 27d, the pattern wiring 28c, the detection circuit 23 and the control signal generating circuit 24.

Further, reference numeral 31 denotes a semiconductor chip on which the input buffers 21a and 21b, the monitoring input buffer 22, the detection circuit. 23, the control signal generating circuit 24 and the connection terminals 26a, 26b, 26c and 26d are mounted, and 32 denotes a package substrate on which the pattern wirings 28a, 28b and 28c and the external terminals 29a and 29b, as well as the semiconductor chip 31 are mounted. As shown in FIG. 2, the connection terminals 26a and 26b on the semiconductor chip 31 and the pattern wirings 28a and 28b on the package substrate 32 are connected by the wires 27a and 27b, respectively, and the connection terminals 26c and 26d on the semiconductor chip 31 and the pattern wiring 28c on the package substrate 32 are connected by the wires 27c and 27d, respectively.

In FIG. 2, assuming that the wiring length of the pattern wiring 28a connected to the input buffer 21a is L1, the wiring length of the pattern wiring 28b connected to the input buffer 21b is L2 and the wiring length of the pattern wiring 28c of the input impedance control circuit 25 is L0, the wiring length L0 is set to an average value of the wiring lengths L1 and L2. That is, L0=(L1+L2)/2.

The operation of the semiconductor integrated circuit of the second embodiment will now be described.

The detection circuit 23 detects the input impedance of the monitoring input buffer 22 inclusive of the impedances of the wires 27c and 27d and the pattern wiring 28c. The control signal generating circuit 24 outputs the control signal to the input buffers 21a and 21b and the monitoring input buffer 22 so as to match with a predetermined impedance on the basis of the detected input impedance. The monitoring input buffer 22 and the input buffers 21a and 21b change their input impedances in accordance with the control signal.

Such a control of the input impedances acts as an auto-control function for the change in impedance due to manufacturing dispersion of the semiconductor chip 31 and changes in supply voltage and temperature, and also due to manufacturing dispersion of package constituent members, and the input impedances of the input buffers 21a and 21b are always controlled so as to match with the predetermined input impedance.

By setting the wiring length L0 of the pattern wiring 28c of the input impedance control circuit 25 to the average value of the wiring lengths L1 and L2 of the pattern wirings 28a and 28b connected to the input buffers 21a and 21b, respectively, it is possible to control the input impedances of all the input buffers 21a and 21b with the same accuracy.

As discussed above, according to the second embodiment, since the detection circuit 23 detects the input impedance of the monitoring input buffer 22 inclusive of the impedances of the wires 27c and 27d and the pattern wiring 28c having the wiring length which is an average value of the wiring lengths of the pattern wirings 28a and 28b connected to the input buffers 21a and 21b, respectively, and when the detected input impedance does not match with the predetermined impedance, the control signal generating circuit 24 outputs the control signal for controlling the detected input impedance to the input buffers 21a and 21b and the monitoring input buffer 22 so as to match with the predetermined input impedance, it is possible to actuate the auto-control function for the change in impedance due to manufacturing dispesion of the semiconductor chip 31, changes in supply voltage and temperature and manufacturing dispersion of package constituent members, to always control the input impedances of the input buffers 21a and 21b so as to match with the predetermined input impedance and the input impedances of the input buffers 21a and 21b can be controlled with the same accuracy even if the lengths of the pattern wirings 28a and 28b connected to the input buffers 21a and 21b are not uniform.

While in each of the above embodiments shows the case of the semiconductor integrated circuit using the BGA package in which the connection terminals (pads) on the semiconductor chip and the pattern wiring on the package substrate are connected by the wires, a package having other structure may be used, and for example, a package having a structure where the connection terminals (pads) and the pattern wiring on the package substrate are connected by bumps can take the same effects.

In this case, the detection circuit detects an input/output impedance of a monitoring input/output buffer inclusive of the impedances of the pattern wiring and the bumps on the package substrate, and therefore an auto-control function acts for the change of impedance due to not only manufacturing dispersion of the semiconductor chip or changes in supply voltage and temperature but also manufacturing dispersion of package constituent members, to always control the input/output impedances of the input/output buffers so as to match with the predetermined input/output impedance and the input/output impedances of the input/output buffers can be controlled with the same accuracy.

What is claimed is:

1. A semiconductor integrated circuit in which a plurality of first connection terminals mounted on a semiconductor chip and a plurality of external terminals of a package in which said semiconductor chip is sealed are connected by a plurality of first pattern wirings on a package substrate, comprising:
a plurality of first buffers connected to said plurality of first connection terminals, whose impedances at said first connection terminals can be controlled by a control signal;
a second buffer having the same circuit configuration as said plurality of first buffers, being connected to a second connection terminal on said semiconductor chip, whose impedance at said second connection terminal can be controlled by said control signal;
a second pattern wiring on said package substrate, being connected to said second connection terminal, having a wiring length equal to an average value of wiring lengths of said plurality of first pattern wirings;
a detection circuit for detecting said impedance at said second connection terminal inclusive of an impedance of said second pattern wiring; and
a control signal generating circuit for generating said control signal which controls said impedances of said first and second buffers to match with a predetermined impedance on the basis of said impedance detected by said detection circuit.

2. The semiconductor integrated circuit according to claim 1, wherein
said plurality of first buffers are output buffers and said second buffer is a monitoring output buffer.

3. The semiconductor integrated circuit according to claim 1, wherein
said plurality of first buffers are input buffers and said second buffer is a monitoring input buffer.
